(19) United States
(12) Patent Application Publication
(10) Pub. No.: US 2012/0322245 A1
(43) Pub. Date: Dec. 20, 2012

(54) METHOD OF MANUFACTURING NITRIDE SEMICONDUCTOR DEVICE

(75) Inventor: Akihito OHNO, Tokyo (JP)

(73) Assignee: MITSUBISHI ELECTRIC CORPORATION, Tokyo (JP)

(21) Appl. No.: 13/354,554

(22) Filed: Jan. 20, 2012

(30) Foreign Application Priority Data
Jun. 15, 2011 (JP) 2011-133490

(51) Int. Cl. H01L 21/20

(52) U.S. Cl. 438/478; 257/E21.09

(57) ABSTRACT

A method of manufacturing a nitride semiconductor device includes: forming a high-resistance buffer layer made of a nitride semiconductor having a carbon concentration of at least 10¹⁸ cm⁻³ on a semiconductor substrate by MOCVD, using an organic metal compound as a group III source material and using a hydrazine derivative as a group V source material; and forming a nitride semiconductor layer having a resistance lower than the high-resistance buffer layer on the high-resistance buffer layer.

### BACKGROUND OF THE INVENTION

1. Field of the Invention

The present invention relates to a method of manufacturing a nitride semiconductor device that forms a high-resistance buffer layer made of a nitride semiconductor on a substrate.

2. Background Art

Field effect transistors (FET) using a nitride semiconductor introduce a high-resistance buffer layer to reduce leakage currents in the buffer layer and improve a withstand voltage. A method of achieving high resistance by doping the nitride semiconductor with carbon as an impurity is proposed (e.g., see Japanese Patent Laid-Open No. 2000-68498, Japanese Patent No. 4429459 and Japanese Patent Laid-Open No. 2007-251144). A growth temperature, a growth pressure, a V/III ratio or the like is reduced in a MOCVD, thereby causing the doping of carbon from methyl radical, ethyl radical or the like of group III raw materials.

### SUMMARY OF THE INVENTION

Conventional carbon doping methods reduce a growth temperature, a growth pressure, a V/III ratio or the like, which causes the deviation from optimum crystal growth conditions. This necessarily leads to deterioration of crystal quality, such as resultant nitrogen holes, and leakage currents or the like cannot be sufficiently reduced.

The present invention has been made to solve the above-described problems and it is an object of the present invention to provide a method of manufacturing a nitride semiconductor device capable of avoiding deterioration of crystal quality of a high-resistance buffer layer.

According to the present invention, a method of manufacturing a nitride semiconductor device includes: forming a high-resistance buffer layer made of a nitride semiconductor having carbon concentration controlled to 10¹⁸ cm⁻³ or above on a semiconductor substrate by an MOCVD method using an organic metal compound as a group III raw material and using a hydrazine derivative as a group V raw material; and forming a nitride semiconductor layer having a resistance value lower than the high-resistance buffer layer on the high-resistance buffer layer.

The present invention makes it possible to avoid deterioration of crystal quality of a high-resistance buffer layer.

Other and further objects, features and advantages of the invention will appear more fully from the following description.

### BRIEF DESCRIPTION OF THE DRAWINGS

FIG. 1 is a cross-sectional view illustrating a nitride semiconductor device according to a first embodiment of the present invention.

FIG. 2 is a diagram illustrating NH₃/UDMHy supply molar ratio dependency of carbon concentration.

FIG. 3 is a cross-sectional view illustrating a nitride semiconductor device according to a third embodiment of the present invention.

FIG. 4 is a cross-sectional view illustrating a nitride semiconductor device according to Embodiment 4 of the present invention.

FIG. 5 is a cross-sectional view illustrating a nitride semiconductor device according to a fifth embodiment of the present invention.

### DETAILED DESCRIPTION OF THE PREFERRED EMBODIMENTS

A method of manufacturing a nitride semiconductor device according to the embodiments of the present invention will be described with reference to the drawings. The same components will be denoted by the same symbols, and the repeated description thereof may be omitted.

### First Embodiment

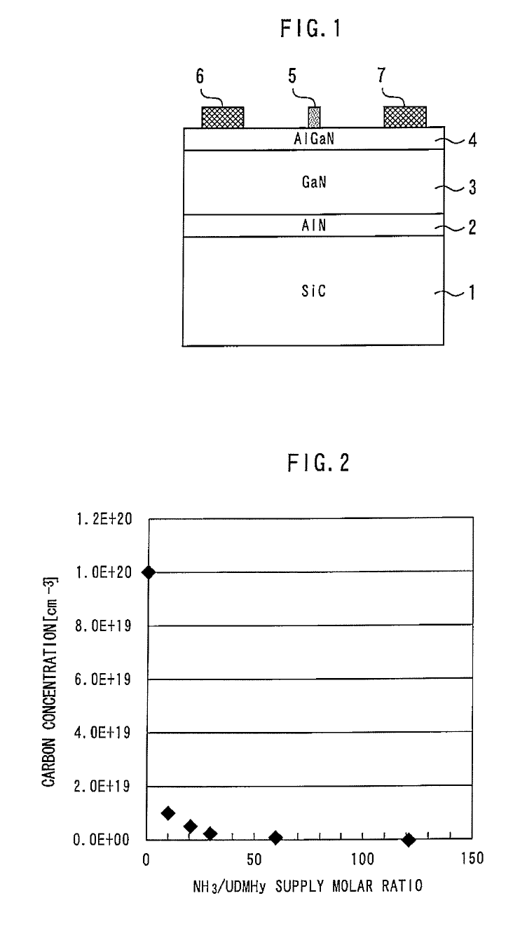

FIG. 1 is a cross-sectional view illustrating a nitride semiconductor device according to a first embodiment of the present invention. An AlN high-resistance buffer layer 2 having a layer thickness of 300 nm is provided on a SiC substrate 1. A GaN electron transit layer 3 having a layer thickness of 1 μm is provided on the AlN high-resistance buffer layer 2. An Al_{0.2}Ga_{0.8}N electron supply layer 4 having a layer thickness of 25 nm is provided on the GaN electron transit layer 3. A gate electrode 5, a source electrode 6 and a drain electrode 7 are provided on the Al_{0.2}Ga_{0.8}N electron supply layer 4. With carbon concentration controlled to 10¹⁸ cm⁻³ or above, the AlN high-resistance buffer layer 2 has a resistance value higher than the GaN electron transit layer 3 and the Al_{0.2}Ga_{0.8}N electron supply layer 4.

Next, a method of manufacturing a nitride semiconductor device according to the first embodiment of the present invention will be described. An MOCVD method is used as a crystal growth method. As a group III raw material, trimethyl gallium (TMG), trimethyl aluminum (TMA) or trimethyl indium (TMI), which is an organic metal compound, is used. As a group V raw material, ammonium (NH₃) gas or dimethylhydrazine (UDMHy) is used. As a carrier gas for these raw gases, a hydrogen (H₂) gas or nitrogen (N₂) gas is used.

First, the AlN high-resistance buffer layer 2 is formed on the SiC substrate 1 using TMA and UDMHy. Next, the GaN electron transit layer 3 is formed on the AlN high-resistance buffer layer 2 using TMG and NH₃. Next, the Al_{0.2}Ga_{0.8}N electron supply layer 4 is formed on the GaN electron transit layer 3. Next, the gate electrode 5, the source electrode 6 and the drain electrode 7 are formed on the Al_{0.2}Ga_{0.8}N electron supply layer 4. A field effect transistor is manufactured through the above-described steps.

When forming the AlN high-resistance buffer layer 2, the present embodiment uses UDMHy as the raw material of group V. This allows the methyl radical freed from TMA or UDMHy to be easily incorporated into a crystal as shown in the following chemical formula without reducing the growth temperature, growth pressure or V/III ratio, and it is thereby possible to obtain a high-resistance crystal without nitrogen holes. Therefore, it is possible to avoid deterioration of crystal quality of the AlN high-resistance buffer layer 2. Furthermore, the carbon concentration of the AlN high-resistance buffer layer 2 is 1×10²⁰ cm⁻³ according to a measurement using secondary ion mass spectroscopy (SIMS) and the specific resistance value of the AlN high-resistance buffer layer 2 is a high-resistance value of 1×10⁶ Ωcm or above according to a measurement using a hole effect method. As a result, it is possible to sufficiently reduce a leakage current of the field effect transistor and secure a sufficient withstand voltage. Furthermore, since the AlN high-resistance buffer layer 2 has a higher resistance value than the SiC substrate 1, it is possible to suppress losses in the substrate and obtain a field effect transistor of good high-frequency characteristics.

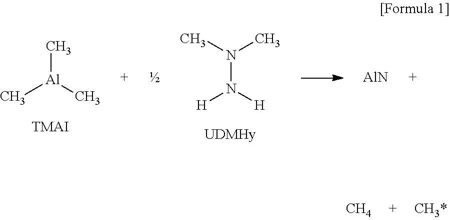

Instead of the SiC substrate 1, a Si substrate, sapphire substrate, GaN substrate or the like may also be used.

### Second Embodiment

A second embodiment uses UDMHy and NH₃ as raw materials of group V when forming an AlN high-resistance buffer layer 2. The rest of the manufacturing method is the same as that of the first embodiment.

FIG. 2 is a diagram illustrating NH₃/UDMHy supply molar ratio dependency of carbon concentration. As is clear from this figure, by setting the supply molar ratio of NH₃ with respect to UDMHy to 30 or less, it is possible to control the carbon concentration to 10¹⁸ cm⁻³ or above without changing the growth temperature or growth pressure which has influences on the crystal quality. As a result, the AlN high-resistance buffer layer 2 having desired resistivity within a range of, for example, 100 Ωcm to 1×10⁷ Ωcm can be obtained, and therefore the structure design can be made easier. By changing the NH₃/UDMHy supply molar ratio during crystal growth, it is also possible to change the carbon concentration in the film thickness direction.

### Third Embodiment

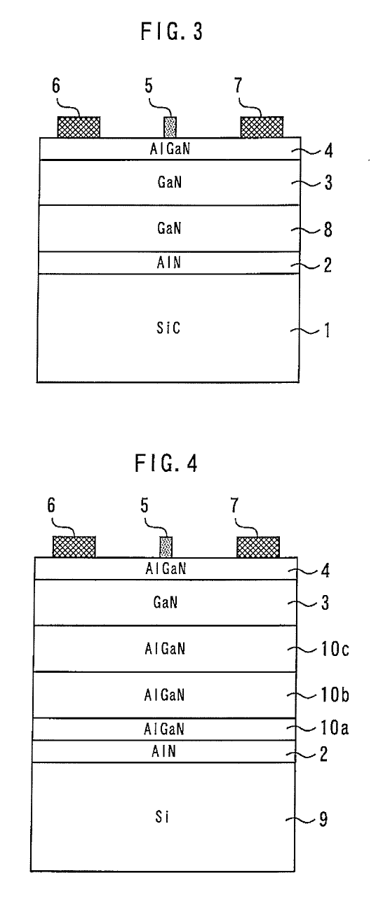

FIG. 3 is a cross-sectional view illustrating a nitride semiconductor device according to a third embodiment of the present invention. An AlN high-resistance buffer layer 2 having a layer thickness of 300 nm is provided on a SiC substrate 1. A GaN high-resistance buffer layer 8 having a layer thickness of 0.5 μm is provided on the AlN high-resistance buffer layer 2. A GaN electron transit layer 3 having a layer thickness of 0.5 μm is provided on the GaN high-resistance buffer layer 8. An Al_{0.2}Ga_{0.8}N electron supply layer 4 having a layer thickness of 25 nm is provided on the GaN electron transit layer 3. A gate electrode 5, a source electrode 6 and a drain electrode 7 are provided on the Al_{0.2}Ga_{0.8}N electron supply layer 4. Since the carbon concentration of the AlN high-resistance buffer layer 2 and the GaN high-resistance buffer layer 8 is controlled to 10¹⁸ cm⁻³ or above, these layers have higher resistance values than the GaN electron transit layer 3 and the Al_{0.2}Ga_{0.8}N electron supply layer 4.

Next, the method of manufacturing a nitride semiconductor device according to the third embodiment of the present invention will be described. First, the AlN high-resistance buffer layer 2 is formed on the SiC substrate 1 using TMA and UDMHy as in the case of the first embodiment. Next, the GaN high-resistance buffer layer 8 is formed on the AlN high-resistance buffer layer 2 using TMG and UDMHy.

Next, as in the case of the first embodiment, the GaN electron transit layer 3, Al_{0.2}Ga_{0.8}N electronic supply layer 4, gate electrode 5, source electrode 6 and drain electrode 7 are formed. A field effect transistor is manufactured through the above-described steps.

The present embodiment uses UDMHy as a group V raw material when forming the GaN high-resistance buffer layer 8. This allows methyl radical freed from TMG or UDMHy to be easily incorporated into crystal as shown in the following chemical formula without reducing the growth temperature, growth pressure, V/III ratio or the like, and it is thereby possible to obtain high-resistance crystal without nitrogen holes. Therefore, it is possible to avoid deterioration of crystal quality of the GaN high-resistance buffer layer 8. Furthermore, the carbon concentration of the GaN high-resistance buffer layer 8 is 1×10²⁰ cm⁻³ according to a measurement using secondary ion mass spectroscopy (SIMS) and the specific resistance value of the GaN high-resistance buffer layer 8 is a high-resistance value of 1×10⁶Ωcm or above according to a measurement using a hole effect method. As a result, it is possible to sufficiently reduce a leakage current of the field effect transistor and secure a sufficient withstand voltage.

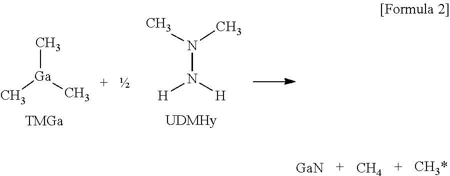

Furthermore, since the AlN high-resistance buffer layer 2 and the GaN high-resistance buffer layer 8 are laminated together, it is also possible to reduce leakage paths in the interface between the SiC substrate 1 and AlN high-resistance buffer layer 2 and the interface between the AlN high-resistance buffer layer 2 and the GaN high-resistance buffer layer 8. Furthermore, since the AlN high-resistance buffer layer 2 and the GaN high-resistance buffer layer 8 have higher resistance values than the SiC substrate 1, it is possible to suppress losses in the substrate and obtain a field effect transistor of good high-frequency characteristics.

When forming the GaN high-resistance buffer layer 8, UDMHy and NH₃ may also be used as the raw materials of group V. Setting the supply molar ratio of NH₃ with respect to UDMHy to 30 or less allows the carbon concentration to be controlled to 10¹⁸ cm⁻³ or above without changing the growth temperature or growth pressure that has influences on the crystal quality. As a result, the GaN high-resistance buffer layer 8 having desired resistivity within a range of, for example, 100 Ωcm to 1×10⁷ Ωcm, and therefore the structure design can be made easier.

Furthermore, a Si substrate, sapphire substrate, GaN substrate or the like may also be used instead of the SiC substrate 1. The AlN high-resistance buffer layer 2 has been taken as an example, but without being limited to this, any optimum layer may be selected according to the structure material of the semiconductor substrate.

Furthermore, instead of the GaN high-resistance buffer layer 8, an Inₓ₁Al_{y1}Ga_{1-x1-y1}N (0<=×1, 0<=y1, x1+y1<1) layer which is a mixed crystal of GaN, AlN and InN may also be used. When forming this layer, TMA, TMG and TMI are used as raw materials of group III and UDMHy alone or UDMHy and NH₃ are used as raw materials of group V.

### Fourth Embodiment

FIG. 4 is a cross-sectional view illustrating a nitride semiconductor device according to Embodiment 4 of the present invention. An AlN high-resistance buffer layer 2 having a layer thickness of 200 nm is provided on a Si substrate 9. A plurality of AlGaN high-resistance buffer layers 10a, 10b and 10c having different mixed crystal ratios are provided on the AlN high-resistance buffer layer 2. For example, the plurality of AlGaN high-resistance buffer layers 10a, 10b and 10c are an Al_{0.5}Ga_{0.5}N layer having a layer thickness of 300 nm, an Al_{0.3}Ga_{0.7}N layer having a layer thickness of 500 nm and an Al_{0.2}Ga_{0.8}N layer having a layer thickness of 500 nm respectively.

A GaN electron transit layer 3 having a layer thickness of 1.0 μm is provided on the AlGaN high-resistance buffer layer 10c. An Al_{0.2}Ga_{0.8}N electron supply layer 4 having a layer thickness of 25 nm is provided on the GaN electron transit layer 3. A gate electrode 5, a source electrode 6 and a drain electrode 7 are provided on the Al_{0.2}Ga_{0.8}N electron supply layer 4.

Since the carbon concentration of the AlN high-resistance buffer layer 2 and the plurality of AlGaN high-resistance buffer layers 10a, 10b and 10c is controlled to 10¹⁸ cm⁻³ or above, these layers have higher resistance values than the GaN electron transit layer 3 and Al_{0.2}Ga_{0.8}N electron supply layer 4.

Next, a method of manufacturing a nitride semiconductor device according to Embodiment 4 of the present invention will be described. First, the AlN high-resistance buffer layer 2 is formed on the Si substrate 9 using TMA and UDMHy as in the case of Embodiment 1. Next, the plurality of AlGaN high-resistance buffer layers 10a, 10b and 10c having different mixed crystal ratios are formed on the AlN high-resistance buffer layer 2 using TMG and TMA as raw materials of group III and using UDMHy alone or UDMHy and NH₃ as raw materials of group V.

Next, the GaN electron transit layer 3, Al_{0.2}Ga_{0.8}N electron supply layer 4, gate electrode 5, source electrode 6 and drain electrode 7 are formed as in the case of the first embodiment. A field effect transistor is manufactured through the above-described steps.

When nitride layers such as the GaN electron transit layer 3 and the Al_{0.2}Ga_{0.8}N electron supply layer 4 are formed on the Si substrate 9, due to a lattice constant difference and a thermal expansion coefficient difference between Si and nitride semiconductor, very large distortion occurs in the nitride semiconductor layer. Depending on the magnitude of distortion, cracks may be produced in the nitride semiconductor layer and a large warp may be produced. By contrast, since the plurality of AlGaN high-resistance buffer layers 10a, 10b and 10c having different mixed crystal ratios reduce distortion in the present embodiment, it is possible to obtain a good field effect transistor without cracks and with less warpage. Furthermore, the use of the Si substrate 9 as the semiconductor substrate can realize a low cost and large diameter product, but since the resistivity of the Si substrate 9 is lower than a sapphire substrate or SiC substrate, the Si substrate 9 is disadvantageous in terms of high-frequency characteristics. However, since the AlN high-resistance buffer layer 2 and AlGaN high-resistance buffer layers 10a, 10b and 10c have higher resistance values than the Si substrate 9, these layers can suppress losses in the Si substrate 9 and can obtain a field effect transistor having good high-frequency characteristics. For this reason, when manufacturing a field effect transistor on a semiconductor substrate having a low resistance value, it is preferable to use a high-resistance buffer layer having higher resistivity than the substrate, for example, 1×10⁶Ωcm or above.

Instead of the plurality of AlGaN high-resistance buffer layers 10a, 10b and 10c having different mixed crystal ratios, an AlGaN high-resistance buffer layer with continuously changed mixed crystal ratios may also be used.

### Fifth Embodiment

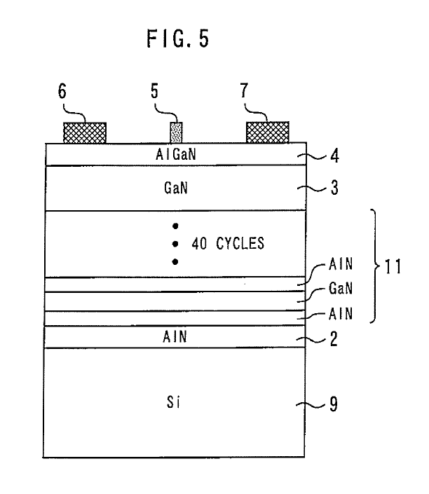

FIG. 5 is a cross-sectional view illustrating a nitride semiconductor device according to a fifth embodiment of the present invention. A high-resistance buffer layer 11 in which AlN layers having a layer thickness of 5 nm and GaN layers having a layer thickness of 15 nm are alternately laminated in 40 cycles is provided instead of the plurality of AlGaN high-resistance buffer layers 10a, 10b and 10c of the fourth embodiment. The rest of the configuration is similar to that of the fourth embodiment.

The AlN layer is formed using TMA as a group III raw material and using UDMHy alone or UDMHy and NH₃ as raw materials of group V. The GaN layer is formed using TMG as a group III raw material and using UDMHy alone or UDMHy and NH₃ as raw materials of group V. The rest of the manufacturing method is similar to that of the fourth embodiment.

Since the high-resistance buffer layer 11 made up of multilayer film reduces distortion, it is possible to obtain a good field effect transistor without cracks and with less warpage. Although the high-resistance buffer layer 11 has a periodic structure in which the AlN layers and GaN layers are alternately laminated in the present embodiment, it is also possible to use a periodic structure of InAlGaN layers having different mixed crystal ratios.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2011-133490, filed on Jun. 15, 2011 including specification, claims, drawings and summary, on which the Convention priority of the present application is based, are incorporated herein by reference in its entirety.

1. A method of manufacturing a nitride semiconductor device comprising:
forming a high-resistance buffer layer made of a nitride semiconductor having a carbon concentration of at least 10¹⁸ cm⁻³ on a semiconductor substrate by MOCVD, using an organic metal compound as a group III, source material and using a hydrazine derivative as a group V source material; and
forming a nitride semiconductor layer having a resistances lower than the high-resistance buffer layer on the high-resistance buffer layer.

2. The method of manufacturing a nitride semiconductor device according to claim 1, wherein the high-resistance buffer layer has a resistance higher than the semiconductor substrate.

3. The method of manufacturing a nitride semiconductor device according to claim 1, including using the hydrazine derivative and ammonia as group V source materials when forming the high-resistance buffer layer.

4. The method of manufacturing a nitride semiconductor device according to claim 3, including supplying the ammonia in a molar ratio with respect to the hydrazine derivative not exceeding 30.

5. The method of manufacturing a nitride semiconductor device according to claim 1, wherein the high-resistance buffer layer includes laminated together, an MN high-resistance buffer layer and a GaN high-resistance buffer layer.

6. The method of manufacturing a nitride semiconductor device according to claim 1, wherein the high-resistance buffer layer includes a plurality of layers having different mixed crystal ratios.

7. The method of manufacturing a nitride semiconductor device according to claim 1, wherein the high-resistance buffer layer has a periodic structure in which layers having different compositions are alternately laminated.
